(19) United States
(12) Patent Application Publication
(10) Pub. No.: US 2014/0340108 A1
(43) Pub. Date: Nov. 20, 2014

(54) TEST ASSEMBLY

(71) Applicant: STAr TECHNOLOGIES, INC., Hsinchu City (TW)

(72) Inventors: Choon Leong LOU, Hsinchu City (TW); Ho Yeh CHEN, Hsinchu City (TW); Li Min WANG, Hsinchu City (TW)

(73) Assignee: STAr TECHNOLOGIES, INC., Hsinchu City (TW)

(21) Appl. No.: 14/275,774

(22) Filed: May 12, 2014

(30) Foreign Application Priority Data
May 15, 2013 (TW) 102117282

(51) Int. Cl. G01R 1/04

(52) U.S. Cl. CPC G01R 1/0408
USPC 324/756.03

(57) ABSTRACT

A test assembly adapted to test a semiconductor device is provided. The test assembly includes a main circuit board, a space transformer, a plurality of electrical connection elements, an intermediary stiffener, and a plurality of test probes. The space transformer is disposed on the main circuit board and has a first surface and a second surface opposite to the first surface. The first surface of the space transformer faces the main circuit board. The electrical connection elements are disposed between the main circuit board and the first surface of the space transformer. The space transformer is electrically connected to the main circuit board through the electrical connection elements. The intermediary stiffener is disposed between the main circuit and the first surface of the space transformer. The intermediary stiffener has a plurality of accommodating through holes. Each of the electrical connection elements is disposed in one of the accommodating through holes. The test probes are disposed on the second surface of the space transformer and electrically connected to the space transformer.

### CROSS REFERENCE TO RELATED APPLICATIONS

This application is based on and claims the benefit of priority from Taiwan Patent Application 102117282 filed on May 15, 2013, which is incorporated herein by reference and assigned to the assignee herein.

### FIELD OF THE INVENTION

The present invention is related to a test assembly and in particular, to a test assembly used to test a semiconductor device.

### DESCRIPTION OF THE PRIOR ART

FIG. 1 is a schematic view of a conventional test assembly. Referring to FIG. 1, the conventional test assembly 100 is adapted to test a semiconductor device 10, such as a wafer. The test assembly 100 comprises a main circuit board 110, a space transformer 120, a plurality of solder balls 130, a plurality of test probes 140 and an underfill 150. The space transformer 120 is disposed on the main circuit board 110. The solder balls 130 are disposed between the main circuit board 110 and the space transformer 120. The space transformer 120 is electrically connected to the main circuit board 110 through the solder balls 130. The test probes 140 disposed on another side of the space transformer 120 are opposite to the solder balls 130 and electrically connected to the space transformer 120.

The underfill 150 is filled between the main circuit board 110 and the space transformer 120 to enclose the solder balls 130. The underfill 150 mitigates the thermal stress causing fatigue at the junctions of the solder balls 130 to enhance the reliability of the points at which the main circuit board 110 and the space transformer 120 are soldered to the solder balls 130.

During the test process performed by the test assembly 100 on the semiconductor device 10, the semiconductor device 10 positioned on a stage (not shown) thrusts upward and impacts on the test probes 140 with specific pressure. At this time, the underfill 150 and the solder balls 130 are also influenced by the aforesaid pressure. However, having been thrust and hit frequently or for a long period of time, the underfill 150 cannot fully protect the solder balls 130 such that the good electrical connection between the main circuit board 110 and the space transformer 120 fails to remain. As a result, after being used longer or frequently, part of the solder balls 130 of the conventional test assembly 100 are likely to have cracks and even fracture such that the electrical connection between the main circuit board 110 and the space transformer 120 is reversely affected.

Moreover, in the event of the aforesaid deterioration of electrical connection, a user who wants to dismount and reset the solder balls 130 will be hindered due to adhesion caused by the presence of the underfill 150.

### SUMMARY OF THE INVENTION

The present invention provides a test assembly, wherein during a test process, defects of electrical connection elements between a main circuit board and a space transformer due to pressure exerted thereon are not easily produced.

The present invention provides a test assembly, wherein electrical connection elements between a main circuit board and a space transformer can be easily dismounted and reset because of the absence of the aforesaid adhesion of the underfill.

The present invention provides a test assembly adapted to test a semiconductor device. The test assembly includes a main circuit board, a space transformer, a plurality of electrical connection elements, an intermediary stiffener, and a plurality of test probes. The space transformer is disposed on the main circuit board and has a first surface and a second surface opposite to the first surface. The first surface of the space transformer faces the main circuit board. The electrical connection elements are disposed between the main circuit board and the first surface of the space transformer. The space transformer is electrically connected to the main circuit board through the electrical connection elements. The intermediary stiffener is disposed between the main circuit and the first surface of the space transformer. The intermediary stiffener has a plurality of accommodating through holes. Each of the electrical connection elements is disposed in one of the accommodating through holes. The test probes are disposed on the second surface of the space transformer and electrically connected to the space transformer.

According to an embodiment of the present invention, the compressive strength of the intermediary stiffener is better than the compressive strength of each of the electrical connection elements.

According to an embodiment of the present invention, the intermediary stiffener is a detachable element.

According to an embodiment of the present invention, the electrical connection elements are arranged in an array and disposed between the main circuit board and the first surface, and the electrical connection elements disposed in the accommodating through holes have one-to-one relationship with the accommodating through holes.

According to an embodiment of the present invention, the test assembly further comprises a probe head penetrated by the test probes.

According to an embodiment of the present invention, the intermediary stiffener further comprises a main body and an outer frame. The main body is disposed between the main circuit board and the first surface and penetrated by the accommodating through holes. The outer frame is connected to the main body and disposed between the probe head and the main circuit board.

According to an embodiment of the present invention, the test assembly further comprises a holding element disposed on the main circuit board. The holding element presses on the probe head to maintain positional relationship between the probe head, the space transformer, the intermediary stiffener and the main circuit board.

According to an embodiment of the present invention, the test assembly further comprises a main stiffener disposed on the main circuit board. The main stiffener and the intermediary stiffener are disposed at two opposite sides of the main circuit board, respectively.

According to an embodiment of the present invention, the intermediary stiffener is made of one of ceramic and plastic.

According to an embodiment of the present invention, each of the test probes is a vertical type probe.

During the test process performed by the test assembly on the semiconductor device, the intermediary stiffener can bear the greater part of the pressure caused by the semiconductor device thrusting upward and impacting on the test probes such that the electrical connection elements only need to bear the minor part of the pressure. Therefore, compared to the prior art, after being used longer or frequently, the electrical connection elements of the test assembly of each of the embodiments of the present invention are not inclined to have defects such that the good electrical connection between the main circuit board and the space transformer can be still maintained.

The following description, the appended claims, and the embodiments of the present invention further illustrate the features and advantages of the present invention.

### BRIEF DESCRIPTION OF THE DRAWINGS

FIG. 1 is a schematic view of a conventional test assembly.

FIG. 2A is a schematic view of a test assembly according to a first embodiment of the present invention.

FIG. 2B is a schematic top view of the intermediary stiffener shown in FIG. 2A.

FIG. 3 is a schematic top view of an intermediary stiffener 350 according to a second embodiment of the present invention.

FIG. 4A is a schematic view of a test assembly 400 according to a third embodiment of the present invention.

FIG. 4B is a schematic top view of the intermediary stiffener shown in FIG. 4A.

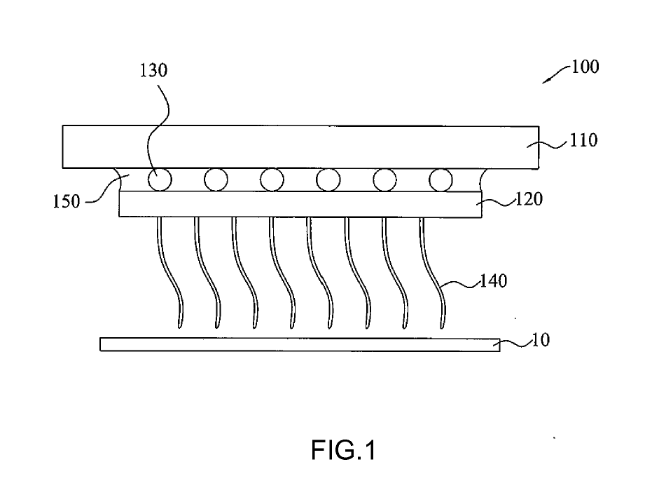

### DETAILED DESCRIPTION OF THE EMBODIMENTS

### First Embodiment

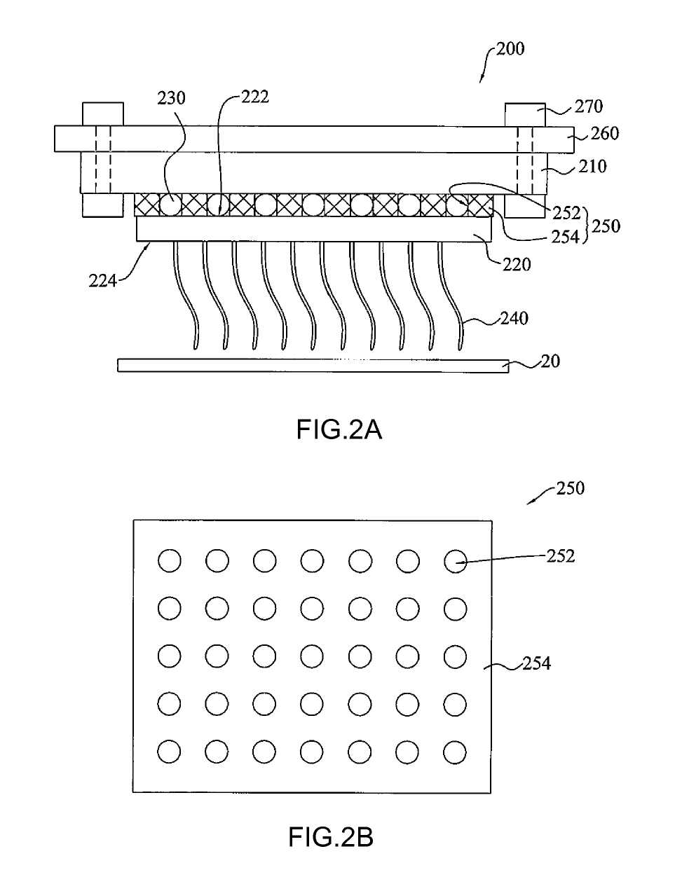

FIG. 2A is a schematic view of a test assembly according to a first embodiment of the present invention. Referring to FIG. 2A, the test assembly 200 in the first embodiment is adapted to test a semiconductor device 20, such as a wafer. The test assembly 200 comprises a main circuit board 210, a space transformer 220, a plurality of electrical connection elements 230, a plurality of test probes 240, and an intermediary stiffener 250. The space transformer 220 is disposed on the main circuit board 210 and has a first surface 222 and a second surface 224 opposite to the first surface 222. The first surface 222 of the space transformer 220 faces the main circuit board 210. Each of the electrical connection elements 230 is, for example, a solder ball made of a material including tin. The electrical connection elements 230 are disposed between the main circuit board 210 and the first surface 222 of the space transformer 220. The space transformer 220 is electrically connected to the main circuit board 210 through the electrical connection elements 230. Specifically speaking, one of a plurality of electrical pads (not shown) disposed on the first surface 222 of the space transformer 220 is electrically connected to one of a plurality of electrical pads (not shown) of the main circuit board 210 through one of the electrical connection elements 230. Moreover, the space transformer 220 has a circuit therein and thus may be regarded as a substrate.

The test probes 240 are disposed on the second surface 224 of the space transformer 220 and electrically connected to the space transformer 220. In this embodiment, each of the test probes 240 is, for example, a vertical type probe, such as a buckling beam probe. In addition to the vertical type probe, each of the test probes can be a probe of any type but is not shown in any figure.

FIG. 2B is a schematic top view of the intermediary stiffener shown in FIG. 2A. Referring to FIG. 2A and FIG. 2B, the intermediary stiffener 250 is disposed between the main circuit board 210 and the first surface 222 of the space transformer 220. The intermediary stiffener 250 comprises a plurality of accommodating through holes 252 and a main body 254. The accommodating through holes 252 penetrate the main body 254. Moreover, the intermediary stiffener 250 is made of any material not electrically conductive, such as ceramic or plastic. In this embodiment, the intermediary stiffener 250 is not adhered to the main circuit board 210 and the space transformer 220 and thus the intermediary stiffener 250 is a detachable element.

Each of the electrical connection elements 230 is disposed in one of the accommodating through holes 252. The compressive strength of the intermediary stiffener 250 may be better than the compressive strength of each of the electrical connection elements 230. In this embodiment, for example, the electrical connection elements 230 are arranged in an array and disposed between the main circuit board 210 and the first surface 222 of the space transformer 220. For example, the electrical connection elements 230 disposed in the accommodating through holes 252 have one-to-one relationship with the accommodating through holes 252.

In this embodiment, the test assembly 200 further comprises a main stiffener 260 and a plurality of fasteners 270. Each of the fasteners 270 is a bolt, for example. The main stiffener 260 is fixedly disposed on the main circuit board 210 by means of the fasteners 270. The main stiffener 260 augments the structural strength of the main circuit board 210. The main stiffener 260 and the intermediary stiffener 250 are disposed on two opposite sides of the main circuit board 210, respectively.

During the test process performed by the test assembly 200 on the semiconductor device 20, the semiconductor device 20 positioned on a stage (not shown) thrusts upward and impacts on the test probes 240 with specific pressure. At this time, the intermediary stiffener 250 and the electrical connection elements 230 are also influenced by the aforesaid pressure. However, the compressive strength of the intermediary stiffener 250 is sufficient to bear the greater part of the aforesaid pressure, and thus the electrical connection elements 230 only need to bear the minor part of the aforesaid pressure. Therefore, compared to the prior art, after being used longer or frequently, the electrical connection elements 230 of the test assembly 200 of the present embodiment are not inclined to have cracks and fracture such that the good electrical connection between the main circuit board 210 and the space transformer 220 can be still maintained.

After being used much longer or frequently, the electrical connection elements 230 become defective inevitably and thus the electrical connection between the main circuit board 210 and the space transformer 220 is reversely affected. However, because the intermediary stiffener 250 is a detachable element, the intermediary stiffener 250 can be detached after the main circuit board 210 and the space transformer 220 is separated and then the electrical connection elements 230 are melted, dismounted, and reset. Therefore, compared to the prior art, the electrical connection elements 230 of the test assembly 200 of the present embodiment can be easily dismounted and reset.

### Second Embodiment

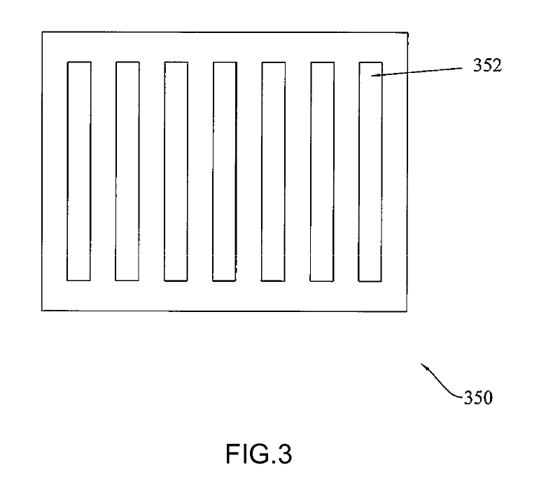

FIG. 3 is a schematic top view of an intermediary stiffener 350 according to a second embodiment of the present invention. Referring to FIG. 2A, FIG. 2B and FIG. 3, the dimensions of each of the accommodating through holes 352 of the intermediary stiffener 350 in this embodiment are different from those of each of the accommodating through holes 252 of the intermediary stiffener 250 in the first embodiment. The intermediary stiffener 350 in this embodiment can be substituted for the intermediary stiffener 250 in the first embodiment such that at least two of the electrical connection elements 230 are disposed in one of the accommodating through holes 352.

### Third Embodiment

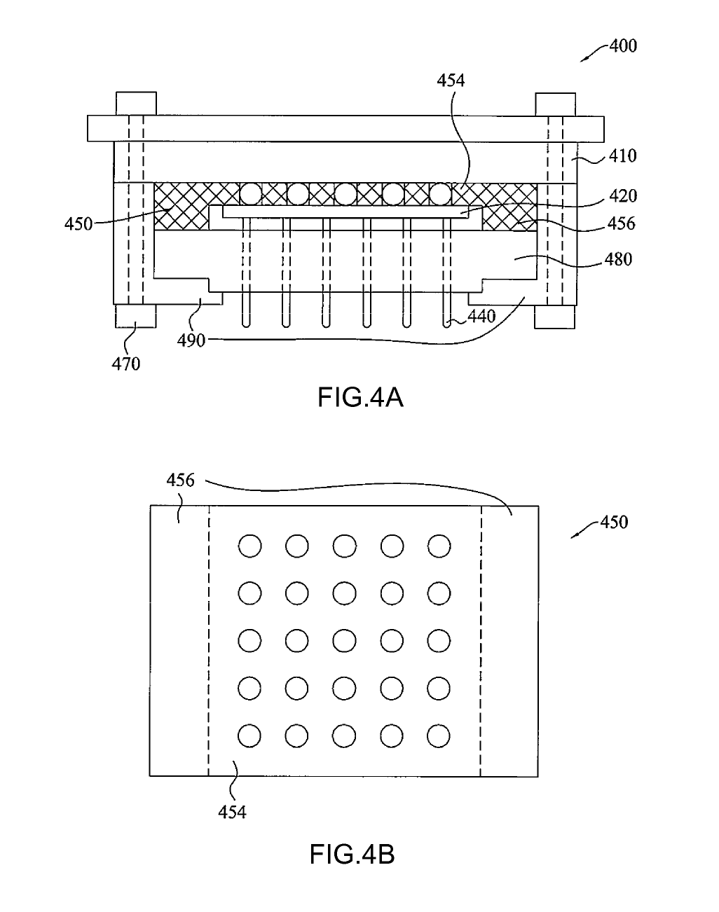

FIG. 4A is a schematic view of a test assembly 400 according to a third embodiment of the present invention. FIG. 4B is a schematic top view of the intermediary stiffener shown in FIG. 4A. Referring to FIG. 2A, FIG. 4A, and FIG. 4B, the difference between the test assembly 400 of the third embodiment and the test assembly 200 of the first embodiment is in that the test assembly 400 further comprises a probe head 480 and a holding element 490 and the intermediary stiffener 450 of the test assembly 400 further comprises an outer frame 456.

The outer frame 456 of the intermediary stiffener 450 is connected to the main body 454. The outer frame 456 is disposed between the probe head 480 and the main circuit board 410. In this embodiment, each of test probes 440 is, for example, a vertical type probe, such as a pogo pin. Each of the test probes 440 penetrates the probe head 480 and is electrically connected to a space transformer 420. The holding element 490 is disposed on the main circuit board 410 by means of the fasteners 470. The holding element 490 presses on the probe head 480 to maintain the positional relationship between the probe head 480, the space transformer 420, the intermediary stiffener 450 and the main circuit board 410.

Each of the aforementioned embodiments of the present invention has one of the following advantages or another advantage. During the test process performed by the test assembly on the semiconductor device, the intermediary stiffener can bear the greater part of the pressure caused by the semiconductor device thrusting upward and impacting on the test probes such that the electrical connection elements only need to bear the minor part of the pressure. Therefore, compared to the prior art, after being used longer or frequently, the electrical connection elements of the test assembly of each of the embodiments of the present invention are not inclined to have defects such that the good electrical connection between the main circuit board and the space transformer can be still maintained.

In addition, after being used much longer or frequently, the electrical connection elements become defective inevitably. However, because the intermediary stiffener is a detachable element, the intermediary stiffener can be detached after the main circuit board and the space transformer is separated and then the electrical connection elements are melted, dismounted, and reset. Therefore, compared to the prior art, the electrical connection elements of the test assembly of each of the embodiments of the present invention can be easily dismounted and reset.

The foregoing detailed description of the embodiments is used to further clearly describe the features and spirit of the present invention. The foregoing description for each embodiment is not intended to limit the scope of the present invention. All kinds of modifications made to the foregoing embodiments and equivalent arrangements should fall within the protected scope of the present invention. Hence, the scope of the present invention should be explained most widely according to the claims described thereafter in connection with the detailed description, and should cover all the possibly equivalent variations and equivalent arrangements.

What is claimed is:

1. A test assembly, adapted to test a semiconductor device, comprising:
a main circuit board;
a space transformer disposed on the main circuit board and having a first surface and a second surface opposite to the first surface, wherein the first surface faces the main circuit board;
a plurality of electrical connection elements disposed between the main circuit board and the first surface, wherein the space transformer is electrically connected to the main circuit board through the electrical connection elements;
an intermediary stiffener disposed between the main circuit board and the first surface, wherein the intermediary stiffener has a plurality of accommodating through holes and each of the electrical connection elements is disposed in one of the accommodating through holes; and
a plurality of test probes disposed on the second surface and electrically connected to the space transformer.

2. The test assembly of claim 1, wherein the compressive strength of the intermediary stiffener is better than the compressive strength of each of the electrical connection elements.

3. The test assembly of claim 1, wherein the intermediary stiffener is a detachable element.

4. The test assembly of claim 1, wherein the electrical connection elements are arranged in an array and disposed between the main circuit board and the first surface, and the electrical connection elements disposed in the accommodating through holes have one-to-one relationship with the accommodating through holes.

5. The test assembly of claim 1, further comprising a probe head penetrated by the test probes.

6. The test assembly of claim 5, wherein the intermediary stiffener further comprises a main body and an outer frame, wherein the main body is disposed between the main circuit board and the first surface and penetrated by the accommodating through holes, and the outer frame is connected to the main body and disposed between the probe head and the main circuit board.

7. The test assembly of claim 5, further comprising a holding element disposed on the main circuit board and pressed on the probe head to maintain positional relationship between the probe head, the space transformer, the intermediary stiffener and the main circuit board.

8. The test assembly of claim 1, further comprising a main stiffener disposed on the main circuit board, wherein the main stiffener and the intermediary stiffener are disposed at two opposite sides of the main circuit board, respectively.

9. The test assembly of claim 1, wherein the intermediary stiffener is made of one of ceramic and plastic.

10. The test assembly of claim 1, wherein each of the test probes is a vertical type probe.
